(19) United States
(12) Patent Application Publication
(10) Pub. No.: US 2025/0331381 A1
(43) Pub. Date: Oct. 23, 2025

(54) DISPLAY PANEL AND DISPLAY DEVICE

(71) Applicant: Wuhan Tianma Microelectronics Co., Ltd., Wuhan (CN)

(72) Inventors: Jue XIONG, Wuhan (CN); Lei LI, Wuhan (CN); Junyan HU, Wuhan (CN)

(73) Assignee: Wuhan Tianma Microelectronics Co., Ltd., Wuhan (CN)

(21) Appl. No.: 19/257,149

(22) Filed: Jul. 1, 2025

Related U.S. Application Data
(63) Continuation of application No. PCT/CN2024/109994, filed on Aug. 6, 2024.

(30) Foreign Application Priority Data
May 31, 2024 (CN) 202410703376.2

(51) Int. Cl. H10K 59/131; G09G 3/3225

(52) U.S. Cl. CPC H10K 59/131; G09G 3/3225; G09G 2300/0842; G09G 2310/08; G09G 2320/0233; G09G 2330/021

(57) ABSTRACT

Provided are a display panel and a display device. A display region includes a first edge and a second edge arranged along a first direction, first signal lines, connection lines and load compensation lines electrically connected to second sub-signal lines. The first signal lines are arranged along the first direction and extend along the first direction, and at least include first sub-signal lines and second sub-signal lines located at a side of the first sub-signal lines away from the first edge. A non-display region includes first fan-out lines and second fan-out lines. The connection lines are electrically connected to the first sub-signal lines and the first fan-out lines, and the second fan-out lines are electrically connected to the second sub-signal lines. A resistance value of the load compensation line electrically connected to the second sub-signal line gradually decrease along a direction from the first edge to the second edge.

### CROSS-REFERENCE TO RELATED APPLICATION

This application is a continuation of International Application No. PCT/CN2024/109994, filed on Aug. 6, 2024, which claims priority to Chinese Patent Application No. 202410703376.2, filed on May 31, 2024. All of the aforementioned applications are hereby incorporated by reference in their entireties.

### TECHNICAL FIELD

The present disclosure relates to the field of display technologies, and in particular, to a display panel and a display device.

### BACKGROUND

With continuous development of science and technology, more and more display devices are widely used in people's daily life and work, and become an indispensable and important tool for people today. Moreover, with the continuous development of display technologies, the requirements of consumers for displays are continuously increasing, various displays emerge, and various display technologies such as liquid crystal display and active display technologies such as organic light-emitting diode display appear. An organic light-emitting diode display panel has become a mainstream display technology in the market due to advantages such as simple manufacturing process, low cost, high light-emitting efficiency, easy formation of flexible structures, low power consumption, high color saturation, and wide viewing angle, etc.

However, the existing organic light-emitting diode (OLED) display panels have relatively wide bezels, and the display effect is affected due to uneven brightness.

### SUMMARY

In view of this, the present disclosure provides a display panel and a display device, aiming to reducing a width of a non-display region of the display panel and improving display uniformity of the display panel.

In a first aspect, an embodiment of the present disclosure provides a display panel, including: a display region and a non-display region, the display region includes first signal lines and connection lines, and the first signal lines are arranged along a first direction and extend along a second direction; the display panel further includes a first edge and a second edge arranged along the first direction; the first signal lines at least include first sub-signal lines and second sub-signal lines, and the second sub-signal lines are located at a side of the first sub-signal lines away from the first edge; the non-display region includes first fan-out lines and second fan-out lines, the connection lines are electrically connected to the first sub-signal lines and the first fan-out lines, and the second fan-out lines are electrically connected to the second sub-signal lines; and the display panel further includes load compensation lines electrically connected to the second sub-signal lines; and for resistance values of the load compensation lines electrically connected to the second sub-signal lines, the resistance values of at least two of the load compensation lines electrically connected to the second sub-signal lines are different from each other, and the resistance values of the load compensation lines electrically connected to the second sub-signal lines gradually decrease along a direction from the first edge to the second edge.

In a second aspect, an embodiment of the present disclosure provides a display device including the above display panel.

According to the display panel and the display device provided by the embodiments of the present disclosure, the connection line connected to the first sub-signal line is arranged in the display region, and the first fan-out line connected to the first sub-signal line can be moved from the edge fan-out region to a side, away from the first edge, of an edge fan-out region, thereby reducing a number of fan-out lines in the edge fan-out region corresponding to the first sub-signal lines in the first direction, and thus reducing a width of the non-display region. Moreover, in the embodiments of the present disclosure, the load compensation line is electrically connected to the second sub-signal line, a load difference between the first sub-signal line and the second sub-signal line can be balanced, thereby improving the display uniformity of the sub-pixels connected to the first sub-signal line and the second sub-signal line, and thus avoiding the problem of uneven display. Moreover, along the direction from the first edge to the second edge, in the embodiments of the present disclosure, the resistance value of the load compensation line electrically connected to the second sub-signal line gradually decreases, which is beneficial to reducing the power consumption of the display panel while improving the brightness consistency of the sub-pixels electrically connected to the first sub-signal line and the sub-pixels electrically connected to the second sub-signal line.

### BRIEF DESCRIPTION OF DRAWINGS

In order to better describe the technical solutions in the embodiments of the present disclosure, the drawings desired in the description of the embodiments will be briefly given as follows. The drawings in the following description are only some of the embodiments of the present disclosure. For those ordinarily skilled in the art, other drawings can also be obtained in accordance with these drawings.

FIG. 1 is a schematic diagram of a display panel according to an embodiment of the present disclosure;

FIG. 2 is an equivalent circuit diagram of a sub-pixel according to an embodiment of the present disclosure;

FIG. 3 is a schematic diagram of the operating timing of a pixel driving circuit according to an embodiment of the present disclosure;

FIG. 4 is a schematic diagram of another display panel according to an embodiment of the present disclosure;

FIG. 5 is a schematic diagram of another display panel according to an embodiment of the present disclosure;

FIG. 6 is a schematic wiring diagram of a pixel driving circuit according to an embodiment of the present disclosure;

FIG. 7 is a partially enlarged schematic diagram of a display panel according to an embodiment of the present disclosure;

FIG. 8 is a cross-sectional view of FIG. 7 along BB′;

FIG. 9 is a schematic diagram of another display panel according to an embodiment of the present disclosure;

FIG. 10 is a schematic diagram of another display panel according to an embodiment of the present disclosure;

FIG. 11 is a schematic diagram of another display panel according to an embodiment of the present disclosure;

FIG. 12 is a partially enlarged schematic diagram of another display panel according to an embodiment of the present disclosure;

FIG. 13 is a cross-sectional view of FIG. 12 along CC′;

FIG. 14 is a schematic diagram of another display panel according to an embodiment of the present disclosure;

FIG. 15 is a schematic diagram of another display panel according to an embodiment of the present disclosure;

FIG. 16 is a schematic diagram of another display panel according to an embodiment of the present disclosure;

FIG. 17 is a schematic diagram of another display panel according to an embodiment of the present disclosure;

FIG. 18 is a schematic diagram of another display panel according to an embodiment of the present disclosure;

FIG. 19 is a schematic diagram of another display panel according to an embodiment of the present disclosure;

FIG. 20 is a schematic diagram of relative positions of a load compensation line, a constant signal line and a first electrode according to an embodiment of the present disclosure;

FIG. 21 is a schematic diagram of another display panel according to an embodiment of the present disclosure; and

FIG. 22 is a schematic diagram of a display device according to an embodiment of the present disclosure.

### DESCRIPTION OF EMBODIMENTS

In order to better illustrate the technical solutions of the present disclosure, the following is a detailed description of the embodiments of the present disclosure with reference to the drawings.

It should be clear that the embodiments described are only part of rather than all of the embodiments of the present disclosure. All other embodiments obtained by those skilled in the art based on the embodiments of the present disclosure shall fall within the protection scope of the present disclosure.

The terms used in the embodiments of the present disclosure are merely intended to describe specific embodiments, but not intended to limit the present disclosure. The singular forms of “a”, “an” and “the” used in the embodiments of the present disclosure and the appended claims are also intended to include plural forms, unless clearly indicating others.

It should be understood that the term “and/or” used herein is merely an association relationship describing an associated object, and indicates that there may be three relationships, for example, A and/or B, and may indicate only A, both A and B, and only B. In addition, the symbol “/” in the context generally indicates that the relation between the objects in front and at the back of “/” is an “or” relationship.

It should be understood that, although expressions “first”, “second” are used to describe specific signal lines, these signal lines should not be limited to these terms. These terms are only used to distinguish individual signal lines from each other. For example, without departing from the scope of the embodiments of the present disclosure, a first signal line can also be referred as a second signal line. Similarly, the second signal line can also be referred to as the first signal line.

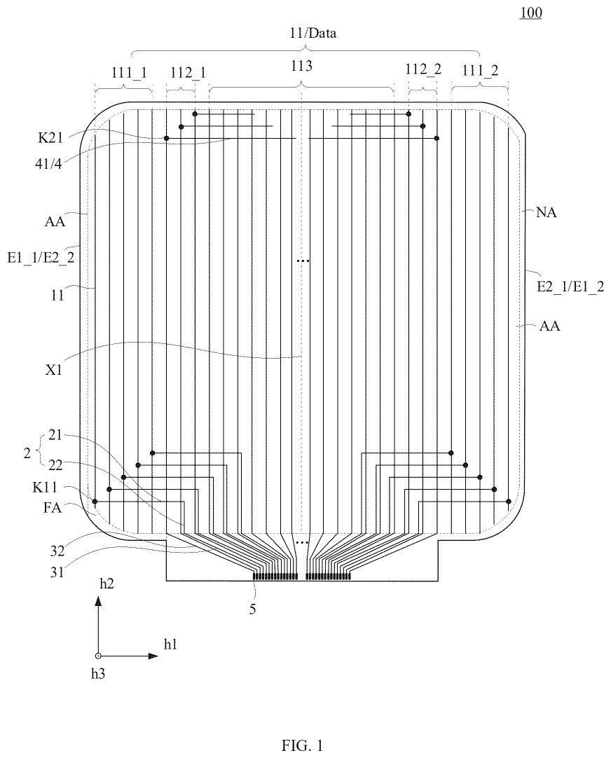

An embodiment of the present disclosure provides a display panel, as shown in FIG. 1, which is a schematic diagram of a display panel according to an embodiment of the present disclosure, the display panel 100 includes a display region AA and a non-display region NA. The non-display region NA at least partially surrounds the display region AA. The display region AA includes sub-pixels (not shown in FIG. 1). The sub-pixel includes a pixel driving circuit and a light-emitting element that are electrically connected to each other.

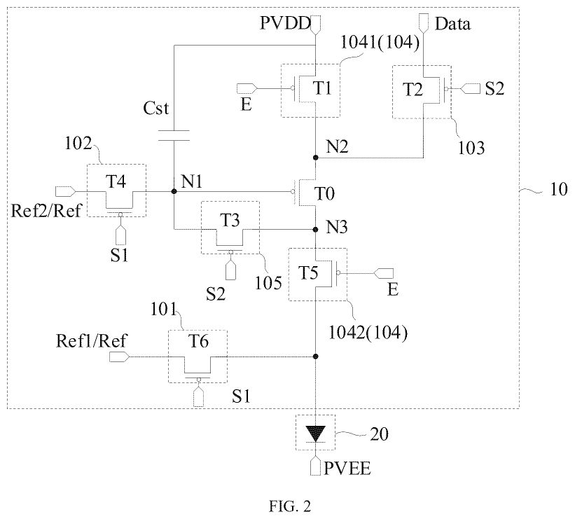

In an embodiment, as shown in FIG. 2, which is an equivalent circuit diagram of a sub-pixel according to an embodiment of the present disclosure, the sub-pixels 1 includes a pixel driving circuit 10 and a light-emitting element 20 that are electrically connected to each other. The pixel driving circuit 10 includes a driving transistor T0, a first reset module 101, a second reset module 102, a data writing module 103, a light-emitting control module 104 and a threshold compensation module 105. A gate electrode of the driving transistor T0 is electrically connected to a first node N1, a first electrode of the driving transistor T0 is electrically connected to a second node N2, and a second electrode of the driving transistor T0 is electrically connected to a third node N3.

The light-emitting control sub-circuit 104 includes a first control sub-circuit 1041 and a second control sub-circuit 1042. An input terminal of the first control sub-circuit 1041 is electrically connected to a first power signal line PVDD. The first power signal line PVDD transmits a first power voltage. An output terminal of the first control sub-circuit 1041 is electrically connected to the first electrode of the driving transistor T0. An input terminal of the second control sub-circuit 1042 is electrically connected to the second electrode of the driving transistor T0, and an output terminal of the second control sub-circuit 1042 electrically connected to a first electrode of the light-emitting element 20. A second electrode of the light-emitting element 20 is electrically connected to a second power signal line PVEE. The second power signal line PVEE transmits a second power voltage. Control terminals of the first control sub-circuit 1041 and the second control sub-circuit 1042 are electrically connected to a light-emitting control signal line E.

A control terminal of the first reset sub-circuit 101 is electrically connected to a first scan line S1, an input terminal of the first reset sub-circuit 101 is electrically connected to a first reset signal line, and an output terminal of the first reset sub-circuit 101 is electrically connected to the first electrode of the light-emitting element 20. A control terminal of the second reset sub-circuit 102 is connected to a first scan line S1, an input terminal of the second reset sub-circuit 102 is electrically connected to a second reset signal line Ref2, and an output terminal of the second reset sub-circuit 102 is electrically connected to a gate electrode of a driving transistor M0.

A control terminal of the data writing module 103 is electrically connected to a second scan line S2, an input terminal of the data writing module 103 is electrically connected to a data signal line Data, and an output terminal of the data writing module 103 is electrically connected to the first electrode of the driving transistor T0. A control terminal of the threshold compensation module 105 is electrically connected to the second scan line S2, an input terminal of the threshold compensation module 105 is electrically connected to the second electrode of the driving transistor T0, and an output terminal of the threshold compensation module 105 is electrically connected to the gate electrode of the driving transistor T0.

Exemplarily, as shown in FIG. 2, the first control sub-circuit 1041 includes a first transistor T1. The data writing sub-circuit 103 includes a second transistor T2. The threshold compensation sub-circuit 105 includes a third transistor T3. The second reset sub-circuit 102 includes a fourth transistor T4. The second control sub-circuit 1042 includes a fifth transistor T5. The first reset sub-circuit 101 includes a sixth transistor T6. The pixel driving circuit 10 further includes a storage capacitor Cst. A first electrode plate of the storage capacitor Cst is electrically connected to the first node N1, and a second electrode plate of the storage capacitor Cst is electrically connected to the first power signal line PVDD.

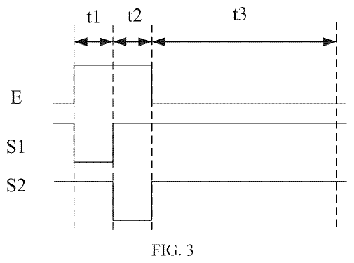

With reference to FIG. 2 and FIG. 3, where FIG. 3 is a schematic diagram of an operation timing of a pixel driving circuit according to an embodiment of the present disclosure, an operation process of the pixel driving circuit 10 includes a resetting stage t1, a charging stage t2, and a light-emitting stage t3.

In the resetting stage t1, the first scan line S1 controls the fourth transistor T4 and the sixth transistor T6 to be turned on, a second reset signal provided by the second reset signal line Ref2 resets the first node N1 through the fourth transistor T4, and the first reset signal provided by the first reset signal line resets the first electrode of the light-emitting element 20 through the sixth transistor T6. For example, the first reset signal may be equal to the second reset signal, or the first reset signal may not be equal to the second reset signal.

In the charging stage t2, the second scan line S2 controls the second transistor T2 to be turned on, and the data voltage Vdata provided by the data signal line Data is written into the second node N2 through the second transistor T2. The driving transistor T0 is turned on. In this stage, the second scan line S2 controls the third transistor T3 to be turned on. During this process, a potential at the first node N1 changes continuously until the potential VN1 at the first node N1 changes to be VN1=Vdata−|Vth|, where Vth is a threshold voltage of the driving transistor T0.

In the light-emitting stage t3, the first transistor T1, the fifth transistor T5 and the driving transistor T0 are turned on, and the light-emitting element 20 electrically connected to the pixel driving circuit 10 is turned on.

In an embodiment of the present disclosure, the display region AA includes first signal lines 11. The first signal lines 11 are arranged along a first direction h1, and the first signal lines 11 each extend along a second direction h2. The first direction h1 intersects with the second direction h2. FIG. 1 illustrates a case that the first direction h1 and the second direction h2 perpendicular to each other. In an embodiment of the present disclosure, one of the first signal lines 11 is electrically connected to multiple pixel driving circuits 10 arranged along the second direction h2.

In an embodiment, as shown in FIG. 1, the data signal line Data includes a first signal line 11.

As shown in FIG. 1, in an embodiment of the present disclosure, the first signal lines 11 at least include first sub-signal lines 111 and second sub-signal lines 112. The second sub-signal line 112 is located at a side of the first sub-signal line 111 away from a first edge E1.

Exemplarily, as shown in FIG. 1, the first sub-signal line 111 and the second sub-signal line 112 are located between the first edge E1 and a first symmetric line X1 of the display region AA. The first symmetric line X1 extends along the second direction h2. The first edge E1 is an edge of two edges opposite to each other along the first direction h1 of the display panel 100, and the first edge E1 has a shortest distance from the first sub-signal line 111. The other edge of the two edges opposite to each other along the first direction h1 of the display panel 100 is a second edge E2. That is, distance between the first sub-signal line 111 and the first edge E1 is less than a distance between the first sub-signal line 111 and the second edge E2, and distance between the second sub-signal line 112 and the first edge E1 is less than a distance between the second sub-signal line 112 and the second edge E2.

According to different positions of the first sub-signal lines 111, positions of the first edge E1 and the second edge E2 may change correspondingly. Exemplarily, as shown in FIG. 1, the first signal lines 11 include two sets of first sub-signal lines and two sets of second sub-signal lines located at two sides of the first symmetric line X1. In FIG. 1, two sets of first sub-signal lines are respectively labeled as 111_1 and 111_2, and two sets of second sub-signal lines are respectively labeled as 112_1 and 112_2. In an embodiment of the present disclosure, the two sets of first sub-signal lines 111 may be symmetrically arranged about the first symmetric line X1 of the display region AA, and the two sets of second sub-signal lines 112 may be arranged about the first symmetric line X1 of the display region AA. Taking orientations shown in FIG. 1 as an example, for the second sub-signal line 112_1 located at a left side of the first symmetric line X1, the first edge E1_1 is a left edge of the display panel 100, and the second edge E2_1 is a right edge of the display panel 100; for the second sub-signal line 112_2 located at a right side of the first symmetric line X1, the first edge E1_2 is a right edge of the display panel 100, and the second edge E2_2 is a left edge of the display panel 100.

With continued reference to FIG. 1, the display region AA further includes connection lines 2. The non-display region NA includes a first fan-out line 31 and a second fan-out line 32. The connection line 2 is electrically connected to the first sub-signal line 111 and the first fan-out line 31, and the second fan-out line 32 is electrically connected to the second sub-signal line 112. That is, the second fan-out line 32 is electrically connected to the second sub-signal line 112 without using the connection line. The first fan-out line 31 and the second fan-out line 32 each are electrically connected to a pin 5, and the pin 5 is electrically bonded to a driver chip (not shown).

In an embodiment of the present disclosure, as shown in FIG. 1, the display panel 100 further includes load compensation lines 4 electrically connected to the second sub-signal lines 112. The load compensation line 4 is configured to increase a load of the second sub-signal line 112 and reduce a load difference between the second sub-signal line 112 and the first sub-signal line 111.

In an embodiment of the present disclosure, along the direction from the first edge E1 to the second edge E2, a resistance value of the load compensation line 4 electrically connected to the second sub-signal line 112 gradually decreases.

When the display panel 100 is in operation, the first sub-signal line 111 can receive a signal provided by the corresponding pin 5 through the connection line 2 located in the display region AA and the first fan-out line 31 located in the non-display region NA, thereby driving sub-pixels electrically connected to the first sub-signal line 111 to light up; and the second sub-signal line 112 may directly receive the driving signal through the second fan-out line 32 located in the non-display region NA, thereby driving sub-pixels electrically connected to the second sub-signal line 112 to light up.

In an embodiment of the present disclosure, the connection lines 2 connected to the first sub-signal line 111 and the corresponding pin 5 are provided in the display region AA, so the first fan-out line 31 connected to the first sub-signal line 111 may be moved from an edge fan-out region FA to a side of the edge fan-out region FA away from the first edge E1, thereby reducing a number of fan-out lines passing through the edge fan-out region FA and provided corresponding to the first sub-signal lines 111, and thus reducing a width of the edge fan-out region FA. As shown in FIG. 1, the edge fan-out region FA refers to a region through which an extension line of the first sub-signal line 111 in the non-display region NA passes. While ensuring the minimum spacing of the fan-out lines in the edge fan-out region FA, based on the solutions provided in the embodiments of the present disclosure, a number of fan-out lines in the edge fan-out region FA may be reduced, or even no fan-out line may be provided in the edge fan-out region FA, thereby reducing the width of the edge fan-out region FA along the second direction h2.

As shown in FIG. 1, when the display panel 100 is designed to be an irregular display panel with an R angle, the extension line of the first sub-signal line 111 passes through the R angle, that is, a contour of the edge fan-out region NA1 is also presented as an arc shape. In the embodiments of the present disclosure, the connection line 2 connected to the first sub-signal line 111 in the irregular display panel is provided in the display region AA, thereby reducing the width of the edge fan-out region NA1 along the second direction h2, and thus improving the visual effect of the irregular display panel.

Due to the fact that the first sub-signal line 111 is connected to the connection line 2, and the second sub-signal line 112 is not connected to the connection line, there is a load difference between the first sub-signal line 111 and the second sub-signal line 112. When displaying on the display panel 100, there is a difference in brightness between the sub-pixels electrically connected to the first sub-signal line 111 and the sub-pixels electrically connected to the second sub-signal line 112. An embodiment of the present disclosure can balance the load difference between the first sub-signal line 111 and the second sub-signal line 112 by providing the load compensation line 4 electrically connected to the second sub-signal line 112. Moreover, along the direction from the first edge E1 to the second edge E2, in an embodiment of the present disclosure, the resistance value of the load compensation line 4 electrically connected to the second sub-signal line 112 gradually decreases, while improving the brightness consistency of the sub-pixels electrically connected to the first sub-signal line 111 and the sub-pixels electrically connected to the second sub-signal line 112, compared with a case that the resistance value of each load compensation line 4 is set to be equal to the resistance value of the load compensation line 4 electrically connected to a first one of the second sub-signal lines 112 (the first one of the second sub-signal lines 112 referring to the second sub-signal line 112 adjacent to the first sub-signal line 111), it can avoid that the resistance values of all the load compensation lines 4 are set to be too large, thereby being beneficial to reducing the power consumption of the display panel 100.

It should be noted that the structure of the pixel driving circuit 10 shown in FIG. 2 and types of the transistors therein are merely illustrative, and according to different design requirements of the display panel, the pixel driving circuit 10 may also be designed as other structures according to the embodiments of the present disclosure. For example, the pixel driving circuit 10 may be designed as a 2T1C structure including two transistors and one storage capacitor, or the pixel driving circuit 10 may be designed as an 8T1C structure including eight transistors and one storage capacitor. In an embodiment, the third transistor T3 or the fourth transistor T4 in FIG. 2 may also be configured to include an oxide transistor. The specific structure of the pixel driving circuit 10 and the specific types of the transistors therein are not limited in the embodiments of the present disclosure.

Exemplarily, in an embodiment of the present disclosure, along the direction from the first edge E1 to the second edge E2, a resistance value difference between the load compensation lines 4 electrically connected to the second sub-signal lines 112 gradually increases. In this way, while balancing the load difference between the first sub-signal line 111 and the second sub-signal line 112 and improving the brightness consistency between the sub-pixels electrically connected to the first sub-signal line 111 and the sub-pixels electrically connected to the second sub-signal line 112, the resistance value difference between two adjacent second sub-signal lines 112 adjacent to the first sub-signal line 111 may be set to be relatively small, and the resistance value difference between two adjacent second sub-signal lines 112 away from the first sub-signal line 111 may be set to be relatively large. The closer the distance between the second sub-signal line 112 and the first sub-signal line 111 is, the easier it is for the inconsistent brightness of the sub-pixels driven by the second sub-signal line 112 and the first sub-signal line 111 to be observed by the human eyes due to load difference. In an embodiment of the present disclosure, the loads of the second sub-signal lines 112 can be compensated more finely by providing the resistance value difference between two adjacent second sub-signal lines 112 adjacent to the first sub-signal line 111 to be relatively small, which is beneficial to improving the display effect; in addition, by providing the resistance value difference between two adjacent second signal sub-lines 112 away from the first signal sub-line 111 to be relatively large, it is possible to avoid providing too many load compensation lines 4 while improving display uniformity, thereby being beneficial to reducing power consumption of the display panel 100.

In an embodiment of the present disclosure, the cross-sectional areas and the electrical conductivities of the load compensation lines 4 electrically connected to two adjacent second sub-signal lines 112 may be the same. Based on this design, along the direction from the first edge E1 to the second edge E2, in an embodiment of the present disclosure, a length value difference between the load compensation lines 4 electrically connected to two adjacent second signal sub-lines 112 may gradually increase, thereby gradually increasing the resistance value difference between the load compensation lines 4 electrically connected to two adjacent second signal sub-lines 112.

In an embodiment, for the resistance values of the resistance load compensation lines 4 along the direction from the first edge E1 to the second edge E2, a resistance value difference between the load compensation lines 4 electrically connected to two adjacent second sub-signal lines 112 is the same as a resistance value difference between the load compensation lines 4 electrically connected to another two adjacent second sub-signal lines 112. Based on this configuration, while reducing the load difference between the first sub-signal line 111 and the second sub-signal line 112 and decreasing the power consumption of the display panel 100, the resistance values of different load compensation lines 4 can be distributed more regularly, thereby reducing the design difficulty of the resistance values of the load compensation lines 4.

In another embodiment of the present disclosure, the cross-sectional areas and the electrical conductivities of the load compensation lines 4 electrically connected to two adjacent second sub-signal lines 112 may be the same. Based on this configuration, in an embodiment of the present disclosure, a length value difference between the load compensation lines 4 electrically connected to two adjacent second signal sub-lines 112 may be the same, so that a resistance value difference between the load compensation lines 4 electrically connected to the two adjacent second signal sub-lines 112 may be the same.

Exemplarily, in an embodiment of the present disclosure, number of the first signal lines 11 is N, a number of the first sub-signal lines 111 is N1, and number of the second sub-signal lines 112 is N2, where N2≤N1<N. As shown in FIG. 1, the first signal lines 11 further includes a third sub-signal line 113. The third sub-signal line 113 is not electrically connected to the connection line and the load compensation line. In an embodiment of the present disclosure, number of the third sub-signal lines 113 is N3. Where N1+N2+N3=N.

In an embodiment, 30%≤N1/N≤40%, for example, N1/N=35%.

Exemplarily, 2%≤N2/N≤8%, for example, N2/N=5%.

In an embodiment of the present disclosure, a length of the connection line 2 electrically connected to the first sub-signal line 111 adjacent to the second sub-signal line 112 is x, and a length value difference between the load compensation lines 4 electrically connected to any two adjacent second sub-signal lines 112 is y, where y=x/N2, thereby resulting in a same resistance value difference between the load compensation lines 4 electrically connected to any two adjacent second sub-signal lines 112.

Exemplarily, in an embodiment of the present disclosure, a length of the connection line 2 electrically connected to the first sub-signal line 111 adjacent to the second sub-signal line 112 is L1, a length of the load compensation line 4 electrically connected to the second sub-signal line 112 adjacent to the first sub-signal line 111 is L21, and a length of the load compensation line 4 electrically connected to the second sub-signal line 112 adjacent to the third sub-signal line 113 is L22, where L1−L21=x/N2, and L22=x/N2. By this configuration, the load difference between the adjacent first sub-signal line 111 and second sub-signal line 112, and the load difference between the adjacent third sub-signal line 113 and second sub-signal line 112 are the same as the load difference between any two adjacent second sub-signal lines 112, so as to improve the display uniformity of the sub-pixels driven by the first sub-signal line 111 and the second sub-signal line 112 respectively, and improve the display uniformity of the sub-pixels driven by the second sub-signal line 112 and the third sub-signal line 113 respectively, thereby improving the display effect of the display panel 100.

It should be noted that the process parameters such as the length and the cross-sectional area involved in the embodiments of the present disclosure are all design values. Due to the limitation of the process accuracy, the actual length and the actual cross-sectional area of the line such as the first signal line 11, the connection line 2, and the load compensation line 4 can vary within an allowable range of the process error. Taking the size precision of the load compensation line 4 as m as an example, when an actual length L21′ of the load compensation line 4 electrically connected to the second sub-signal line 112 adjacent to the first sub-signal line 111 satisfies L21−m≤L21′≤L21+m, it is included in the protection scope of the present disclosure.

In addition, the “same length” and “same cross-sectional area” mentioned in the embodiments of the present disclosure respectively refer to a same length within the range allowed by the process error, and a same cross-sectional area within the range allowed by the process error.

Exemplarily, in an embodiment of the present disclosure, the cross-sectional areas and the electrical conductivities of the connection line 2 and the load compensation line 4 are the same, and/or the cross-sectional areas and the electrical conductivities of the first sub-signal line 111, the second sub-signal line 112, and the third sub-signal line 113 are the same. Based on this configuration, while the load difference between the adjacent first sub-signal line 111 and the second sub-signal line 112, and the load difference between the adjacent third sub-signal line 113 and the second sub-signal line 112, are the same as the load difference between any two adjacent second sub-signal lines 112, only different lengths of the load compensation lines 4 may be adjusted, thereby reducing the design difficulty of the load compensation lines 4.

Exemplarily, as shown in FIG. 1, along the direction from the first edge E1 to the second edge E2, the length of the load compensation line 4 electrically connected to the second sub-signal line 112 gradually decreases, so that the resistance value of the load compensation line 4 electrically connected to the second sub-signal line 112 gradually decreases.

In an embodiment of the present disclosure, different load compensation lines 4 may have a same conductivity and/or a same cross-sectional area. Based on this configuration, the design difficulty of the load compensation lines 4 can be reduced while gradually reducing the resistance value of the load compensation line 4 electrically connected to the second sub-signal line 112.

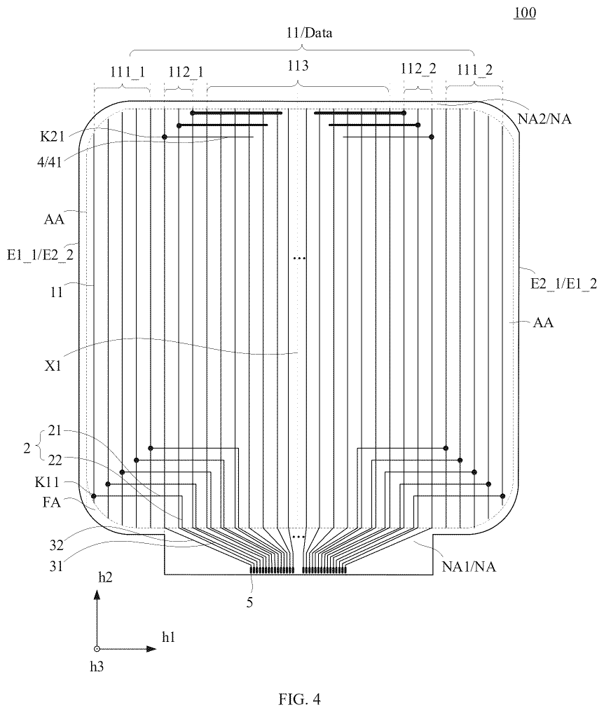

In an embodiment, as shown in FIG. 4, which is a schematic diagram of another display panel according to an embodiment of the present disclosure, along the direction from the first edge E1 to the second edge E2, the cross-sectional area of the load compensation line 4 electrically connected to the second sub-signal line 112 gradually increases, so that a resistance value of the load compensation line 4 electrically connected to the second sub-signal line 112 gradually decreases. The cross-sectional area refers to an area of a cross-section perpendicular to an extension direction of the load compensation line 4. FIG. 4 illustrates load compensation lines 4 having different cross-sectional areas with lines of different thicknesses. In an embodiment of the present disclosure, the change of the cross-sectional area may be achieved by adjusting the thickness and width of the load compensation line 4. The thickness of the load compensation line 4 refers to the size of the cross section along a direction perpendicular to the plane of the display panel 100, and the width of the load compensation line 4 refers to a size of the cross section along a direction parallel to the plane of the display panel 100.

Exemplarily, in an embodiment of the present disclosure, lengths and/or conductivities of different load compensation lines 4 may be the same. Based on this configuration, while gradually decreasing the resistance value of the load compensation line 4 electrically connected to the second sub-signal line 112 along the direction from the first edge E1 to the second edge E2, only a cross-sectional area of the different load compensation line 4 shall be adjusted, so as to reduce design difficulty of the load compensation line 4.

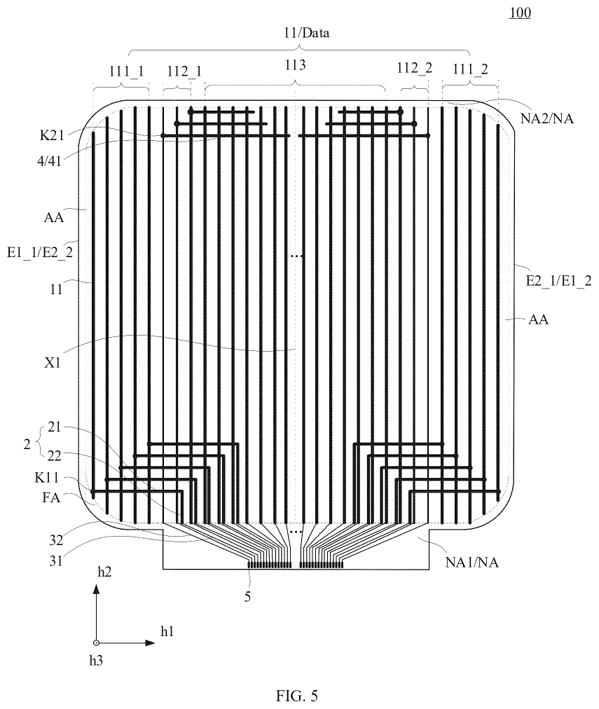

Exemplarily, as shown in FIG. 5, which is a schematic diagram of another display panel according to an embodiment of the present disclosure, along the direction from the first edge E1 to the second edge E2, the cross-sectional area of the second sub-signal line 112 gradually increases, so that the resistance value of the second sub-signal line 112 gradually decreases. Based on the arrangement of the load compensation line 4 described above, it is possible to further reduce the load difference between the first sub-signal line 111 and the second sub-signal line 112, thereby improving the display uniformity of the sub-pixels connected thereto. FIG. 5 illustrates the second sub-signal lines 112 having different cross-sectional areas with lines of different thicknesses. As shown in FIG. 5, a cross-sectional area of the first sub-signal line 111 and a cross-sectional area of the third sub-signal line 113 are the same as a maximum cross-sectional area of the second sub-signal line 112.

In an embodiment of the present disclosure, lengths and/or conductivities of different second sub-signal lines 112 may be set to be the same, and FIG. 5 illustrates that lengths of different second sub-signal lines 112 are set to be the same. Based on this configuration, while gradually decreasing the resistance value of the load compensation line 4 electrically connected to the second sub-signal line 112 along the direction from the first edge E1 to the second edge E2, only a cross-sectional area of the second sub-signal line 112 shall be adjusted, so as to reduce the design difficulty of the second sub-signal line 112.

Exemplarily, at least part of the load compensation lines 4 may be located in the display region AA. FIG. 1, FIG. 4 and FIG. 5 all illustrate that the load compensation line 4 is located in the display region AA. Based on this arrangement, the load compensation line 4 can be prevented from occupying the space of the non-display region NA, thereby reducing the area of the non-display region NA, facilitating the narrow frame design of the display panel 100, and thus improving the screen-to-body ratio of the display panel 100.

In an embodiment, as shown in FIG. 1, FIG. 4 and FIG. 5, the connection line 2 includes a first sub-connection line 21 extending along the first direction h1 and a second sub-connection line 22 extending along the second direction h2. The second sub-connection line 22 is located at a side of the first sub-signal line 111 away from the first edge E1. The load compensation line 4 includes a first sub-compensation line 41 extending along the first direction h1. As shown in FIG. 1, FIG. 4 and FIG. 5, the first sub-compensation line 41 is located in the display region AA to prevent the width of the non-display region NA from being increased due to the first sub-compensation line 41 being provided in the non-display region NA.

Exemplarily, in an embodiment of the present disclosure, the first sub-connection line 21 and the first sub-signal line 111 may be arranged in different layers. As shown in FIG. 1, FIG. 4 and FIG. 5, the first sub-connection line 21 and the first sub-signal line 111 are electrically connected to each other through a first through-hole K11. The first sub-compensation line 41 and the second sub-signal line 112 may be arranged in different layers. As shown in FIG. 1, FIG. 4 and FIG. 5, the first sub-compensation line 41 and the second sub-signal line 112 are electrically connected through a second through-hole K21.

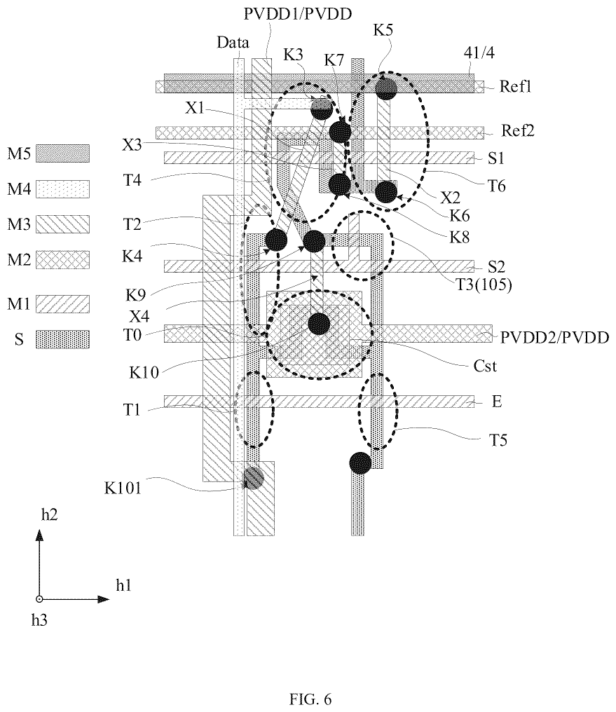

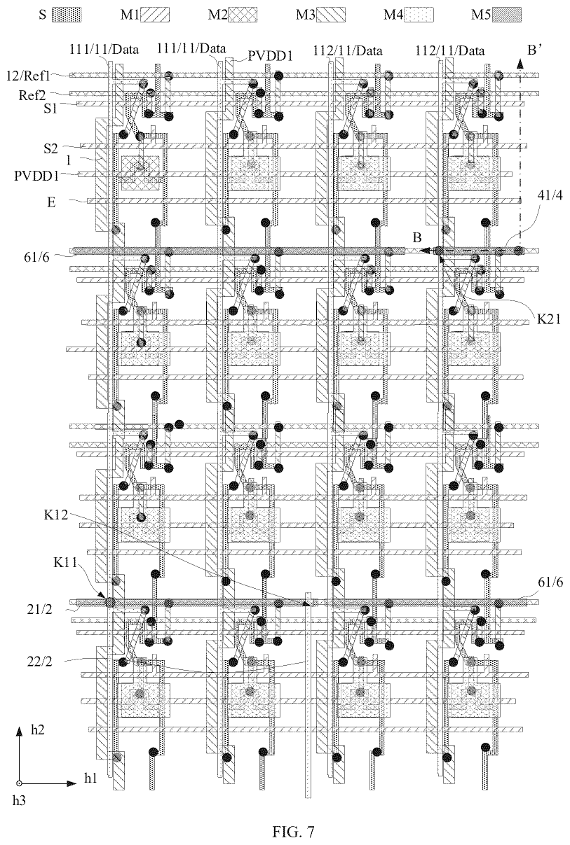

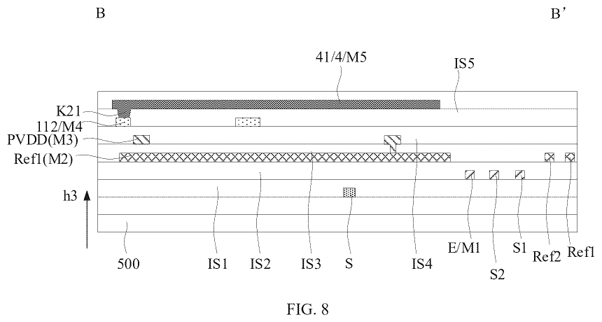

A film layer structure of a display panel provided by an embodiment of the present disclosure is described below with reference to FIG. 6, FIG. 7 and FIG. 8. FIG. 6 is a schematic diagram of wiring of a pixel driving circuit provided by an embodiment of the present disclosure. FIG. 7 is a partial enlarged schematic diagram of a display panel provided by an embodiment of the present disclosure. FIG. 7 shows 4×4 pixel driving circuits arranged in an array along the first direction h1 and the second direction h2. The pixel driving circuits may have a circuit structure as shown in FIG. 2 and FIG. 6, respectively. FIG. 8 is a cross-sectional view of FIG. 7 along BB′. As shown in FIG. 8, the display panel 100 includes a substrate 500, a semiconductor layer S, a first insulation layer IS1, a first conductive layer M1, a second insulation layer IS2, a second conductive layer M2, a third insulation layer IS3, a third conductive layer M3, a fourth insulation layer IS4, a fourth conductive layer M4, a fifth insulation layer IS5, and a fifth conductive layer M5. The semiconductor layer S is located at a side of the substrate 500. The first insulation layer IS1 is located at a side of the semiconductor layer S away from the substrate 500. The first conductive layer M1 is located at a side of the first insulation layer IS1 away from the semiconductor layer S. The second insulation layer IS2 is located at a side of the first conductive layer M1 away from the semiconductor layer S. The second conductive layer M2 is located at a side of the second insulation layer IS2 away from the first conductive layer M1. The third insulation layer IS3 is located at a side of the second conductive layer M2 away from the second insulation layer IS2. The third conductive layer M3 is located at a side of the third insulation layer IS3 away from the second conductive layer M2. The fourth insulation layer IS4 is located at a side of the third conductive layer M3 away from the third insulation layer IS3. The fourth conductive layer is located at a side of the fourth insulation layer IS4 away from the third conductive layer M3. The fifth insulation layer IS5 is located at a side of the fourth conductive layer M4 away from the fourth insulation layer IS4. The fifth conductive layer M5 is located at a side of the fifth insulation layer IS5 away from the fourth conductive layer M4.

Exemplarily, the semiconductor layer S includes a channel region and a doping region for forming the transistor described above. Exemplarily, the doping region includes a source doping region and a drain doping region. The semiconductor layer S includes any one or more of low temperature polysilicon, amorphous silicon, and oxide semiconductor layer.

In an embodiment, the above first scanning line S1, the second scanning line S2, the light-emitting control signal line E, the first reset signal line and the second reset signal line Ref2 may extend along the first direction h1. The first power signal line PVDD and the data signal line Data may extend along the second direction. The extension directions of the signal lines intersect with each other and the signal lines are insulated from each other.

Exemplarily, the first scanning line S1, the second scanning line S2 and the light-emitting control signal line E may be provided in a same layer or different layers. The first reset signal line and the second reset signal line Ref2 may be provided in a same layer or different layers. The first power signal line PVDD and the data signal line Data may be provided in a same layer or different layers.

As shown in FIG. 6, the first electrode plate of the storage capacitor Cst, the first scanning line S1, the second scanning line S2 and the light-emitting control signal line E are provided in the first conductive layer M1. The first reset signal line Ref1, the second reset signal line Ref2 and the second electrode plate of the storage capacitor Cst are provided in the second conductive layer M2. The first power signal line PVDD includes a first sub-power signal line PVDD1 located in the third conductive layer M3 and a second sub-power signal line PVDD2 located in the second conductive layer M2. The data signal line Data is provided in the fourth conductive layer M4. In an embodiment, a material of the conductive layers includes metal or metal alloy. Exemplarily, the material of each conductive layer includes one or more of molybdenum, aluminum, titanium, silver, and copper.

In an embodiment, as shown in FIG. 6, the third conductive layer M3 further includes a first connecting portion X1, a second connecting portion X2, a third connecting portion X3 and a fourth connecting portion X4. The data signal line Data located in the fifth conductive layer M5 is electrically connected to one end of the first connecting portion X1 through a third through-hole K3 penetrating through the fifth insulation layer (not shown). The other end of the first connection portion X1 is electrically connected to the source doping region or the drain doping region of the second transistor T2 located in the semiconductor layer S through the fourth through-hole K4 penetrating through the third insulation layer (not shown), the second insulation layer (not shown) and the first insulation layer (not shown), so as to transmit the data voltage to the second transistor T2.

One end of the second connecting portion X2 is electrically connected to the first reset signal line located in the second conductive layer through a fifth through-hole K5 penetrating through the third insulation layer. The other end of the second connection portion X2 is electrically connected to the source doping region or the drain doping region of the sixth transistor T6 located in the semiconductor layer S through the sixth through-hole K6 penetrating the third insulation layer, the second insulation layer and the first insulation layer, so as to transmit the first reset signal to the sixth transistor T6.

One end of the third connecting portion X3 is electrically connected to the second reset signal line Ref2 located in the second conductive layer through the seventh through-hole K7 penetrating through the third insulation layer. The other end of the third connecting portion X3 is electrically connected to the source doping region or the drain doping region of the fourth transistor T4 located in the semiconductor layer through the eighth through-hole K8 penetrating through the third insulation layer, the second insulation layer and the first insulation layer, so as to transmit the second reset signal to the fourth transistor T4.

One end of the fourth connection portion X4 is electrically connected to the source doping region or the drain doping region of the fourth transistor T4 located in the semiconductor layer through the ninth through-hole K9, and the other end of the fourth connection portion X4 is electrically connected to the first electrode plate of the storage capacitor Cst through the tenth through-hole K10.

As shown in FIG. 6, the first power signal line PVDD includes a first sub-power signal line PVDD1 located in the third conductive layer M3 and a second sub-power signal line PVDD2 located in the second conductive layer M2. The first sub-power signal line PVDD1 is electrically connected to the source doping region or the drain doping region of the first transistor T1 located in the semiconductor layer S through the eleventh through-hole K101, so as to transmit the first power voltage to the first transistor T1.

As shown in FIG. 7, the first sub-signal line 111 and the second sub-signal line 112 are provided on the fourth conductive layer M4, and the first sub-connection line 21 and the first sub-compensation line 41 are provided in the fifth conductive layer M5. As shown in FIG. 8, a fifth insulation layer IS5 is provided between the fourth conductive layer M4 and the fifth conductive layer M5. The fifth insulation layer IS5 includes the second through-hole K21 described above. The second sub-signal line 112 is electrically connected to the first sub-compensation line 41 through the second through-hole K21. In this way, while the first sub-compensation line 41 is electrically connected to the corresponding second sub-signal line 112, good insulation between the first sub-compensation line 41 and other second sub-signal line 112 can be ensured.

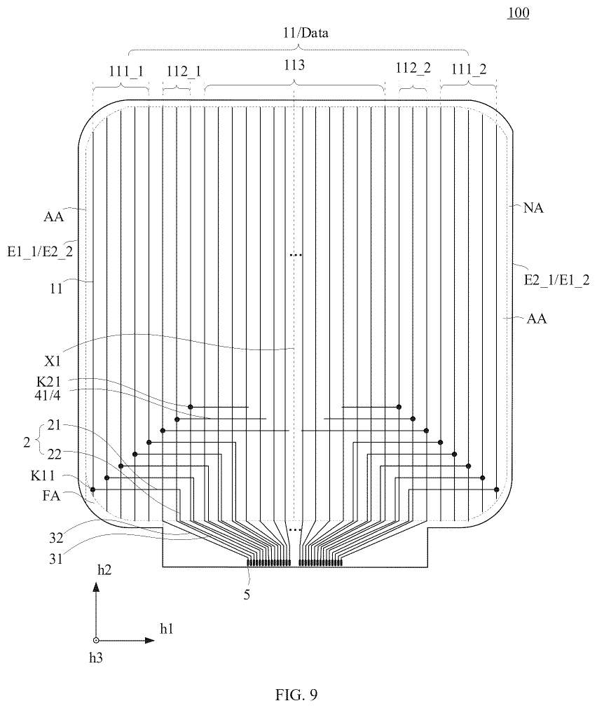

In an embodiment, as shown in FIG. 9, which is a schematic diagram of another display panel according to an embodiment of the present disclosure, a connection line between the first through-holes K11 and the second through-holes K21 is located on a straight line, so that the arrangement of the first through-holes K11 and the second through-holes K21 can be more regular, which is beneficial to improving the distribution uniformity of the through-holes in the display region AA, thereby improving the display effect.

In another implementation, as shown in FIG. 1, FIG. 4, and FIG. 5, an arrangement direction of the first through-holes K11 is parallel to an arrangement direction of the second through-holes K21.

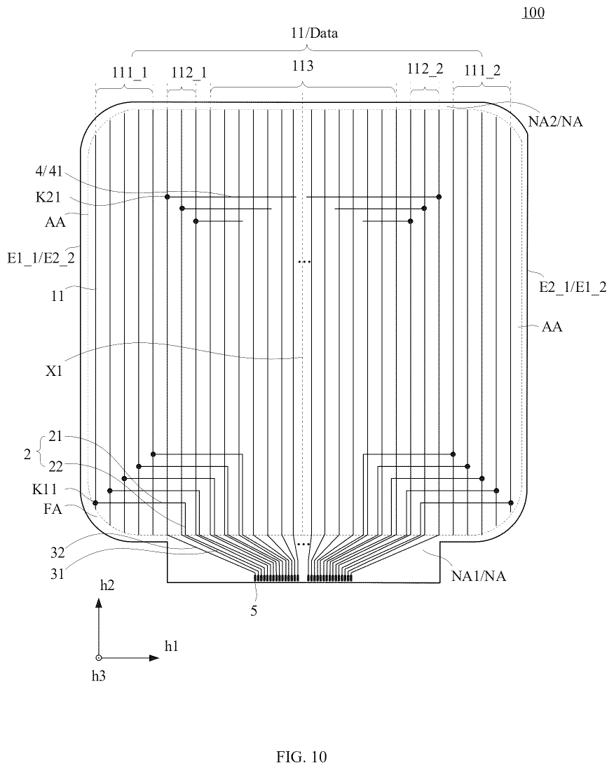

In another implementation, as shown in FIG. 10, which is a schematic diagram of another display panel according to an embodiment of the present disclosure, the arrangement direction of the first through-holes K11 may intersect with the arrangement direction of the second through-holes K21.

Exemplarily, along the direction from the first edge E1 to the second edge E2, the resistance value of the first sub-compensation line 41 electrically connected to the second sub-signal line 112 gradually decreases. Based on this configuration, while balancing the load difference between the first sub-signal line 111 and the second sub-signal line 112 and improving the brightness consistency of the sub-pixels electrically connected to the first sub-signal line 111 and the sub-pixels electrically connected to the second sub-signal line 112, it can avoid that the resistance values of all the first sub-compensation lines 41 are set to be too large, which is beneficial to reducing the power consumption of the display panel 100.

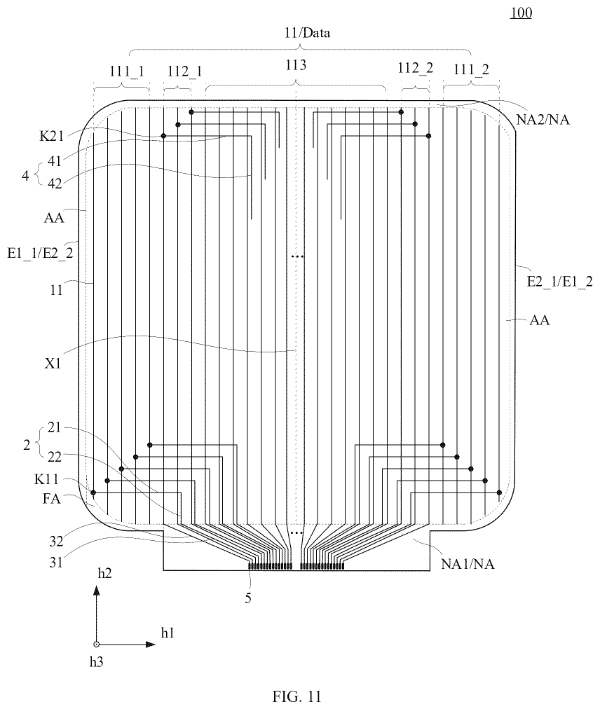

In an embodiment, as shown in FIG. 11, which is a schematic diagram of another display panel according to an embodiment of the present disclosure, in addition to the first sub-compensation line 41, the load compensation line 4 further includes a second sub-compensation line 42 extending along the second direction h2. A resistance value of the second sub-compensation line 42 electrically connected to the second sub-signal line 112 gradually decreases along the direction from the first edge E1 to the second edge E2. In an embodiment of the present disclosure, by providing the first sub-compensation line 41 and the second sub-compensation line 42, the length of the load compensation line 4 in a single direction can be prevented from being set too long while increasing the load of the second sub-signal line 112.

Exemplarily, in an embodiment of the present disclosure, the resistance values of the first sub-compensation lines 41 of different load compensation line 4 may be the same, so that the resistance values of the load compensation lines 4 may be adjusted by only adjusting the length of the second sub-compensation line 42, and the design thereof is simple.

In an embodiment of the present disclosure, at least one of lengths, conductivities, and cross-sectional areas of different first sub-compensation lines 41 may be the same, thereby reducing the design difficulty of the load compensation line 4.

Exemplarily, as shown in FIG. 11, along the direction from the first edge E1 to the second edge E2, in an embodiment of the present disclosure, the lengths of the second sub-compensation lines 42 electrically connected to different second sub-signal lines 112 may be gradually decreased; or, in an embodiment of the present disclosure, the cross-sectional areas of the second sub-compensation lines 42 may be gradually increased to reduce resistance values of different second sub-compensation lines 42.

In an embodiment of the present disclosure, the second sub-compensation line 42 and the second sub-connection line 22 may be arranged in a same layer. In this way, the second sub-compensation line 42 and the second sub-connection line 22 may be formed by a same material in a same patterning process, which is beneficial to simplifying the process flow and reducing the manufacturing cost. Moreover, it is also beneficial to reducing a number of film layers in the display panel 100, thereby enabling a slimmer profile design of the display panel. Exemplarily, the patterning process includes steps such as film formation, photolithography exposure, etching, and development.

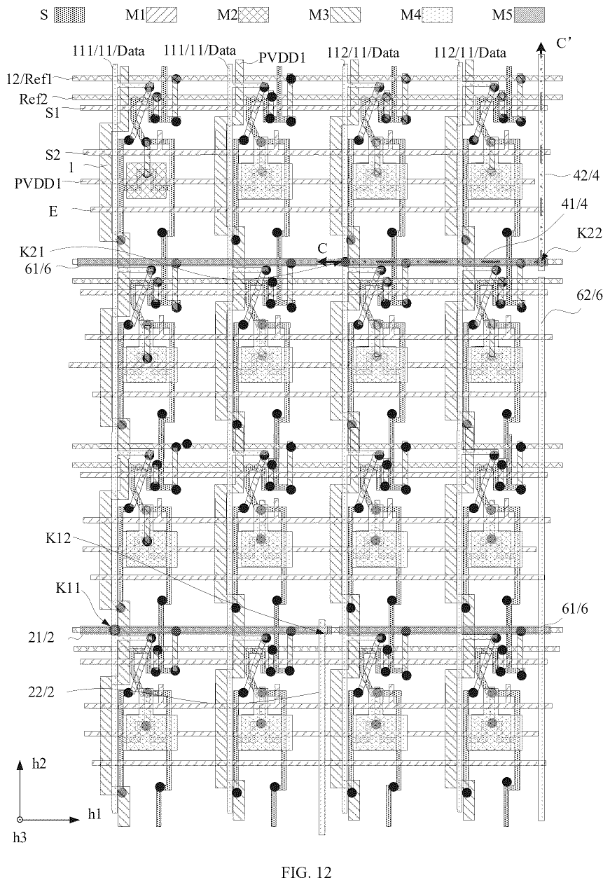

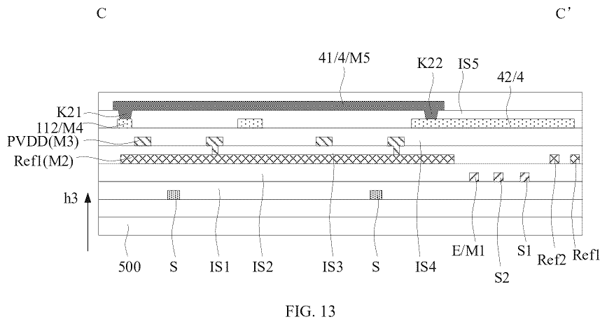

Exemplarily, in an embodiment of the present disclosure, the first sub-compensation line 41 and the second sub-signal line 112 may be arranged in different layers, and the second sub-compensation line 42 and the second sub-signal line 112 may be arranged in a same layer. In this way, the second sub-compensation line 42 and the second sub-signal line 112 may be formed by a same material in a same patterning process, which is beneficial to simplifying the process flow and reducing the manufacturing cost. Moreover, it is also beneficial to reducing a number of film layers in the display panel 100, thereby enabling a slimmer profile design of the display panel. With reference to FIG. 12 and FIG. 13, FIG. 12 is a partially enlarged schematic diagram of another display panel according to an embodiment of the present disclosure, and FIG. 13 is a schematic cross-sectional view of FIG. 12 along CC′, a first sub-signal line 111, a second sub-signal line 112, a second sub-compensation line 42 and a second sub-connection line 22 are all provided in a fourth metal layer M4. As shown in FIG. 12, the first sub-connection line 21 and the second sub-connection line 22 are electrically connected to each other through a twelfth through-hole K12, and the first sub-compensation line 41 and the second sub-compensation line 42 are electrically connected to each other through a thirteenth through-hole K22.

It should be noted that the layout designs of the pixel driving circuit illustrated in FIG. 6, FIG. 7 and FIG. 12, and the distribution of each structure in FIG. 6, FIG. 7, FIG. 12 and FIG. 13 in different film layers are merely illustrative. The layout of the pixel driving circuit and the film layer where each of different structures in the display panel is located may be correspondingly adjusted according to different design requirements of the display panel. For example, in an embodiment of the present disclosure, at least two of the first power sub-signal line PVDD1, the data signal line Data, the second sub-connection line 22 and the second sub-compensation line 42 may be provided in a same layer. For example, the first power sub-signal line PVDD1, the data signal line Data, the second sub-connection line 22 and the second sub-compensation line 42 are all provided in the third conductive layer M3. The first sub-connection line 21 and the first sub-compensation line 41 may be provided in a same layer and arranged at a side of the third conductive layer M3 away from the substrate 500. For example, the first sub-connection line 21 and the first sub-compensation line 41 are all provided in the fourth conductive layer M4. A specific layout design of the pixel driving circuit is not limited in the embodiments of the present disclosure.

Exemplarily, when the first sub-compensation line 41 and the second sub-compensation line 42 are located in different conductive layers, they can be made of a same material or different materials, which is not limited in the embodiments of the present disclosure.

In an embodiment of the present disclosure, the second sub-compensation line 42 and the first sub-compensation line 41 may be provided in a same layer. For example, in an embodiment of the present disclosure, the first sub-power signal line PVDD1 and the data signal line Data are arranged in the third conductive layer M3 in a same layer. The second sub-compensation line 42 and the first sub-compensation line 41 are arranged in the fourth conductive layer M4 in a same layer. The first sub-compensation line 41 is electrically connected to the second sub-signal line 112 through the second through-hole K21. The second sub-compensation line 42 and the first sub-compensation line 41 are directly electrically connected to each other without passing through a through-hole.

Exemplarily, as shown in FIG. 1, FIG. 9 and FIG. 10, when the load compensation line 4 only includes the first sub-compensation line 41, the length of the load compensation line 4 electrically connected to the second sub-signal line 112 gradually decreases along the direction from the first edge E1 to the second edge E2, including: along the direction from the first edge E1 to the second edge E2, the length of the first sub-compensation line 41 electrically connected to the second sub-signal line 112 gradually decreases.

In an embodiment, as shown in FIG. 4, when the load compensation line 4 only includes the first sub-compensation line 41, the cross-sectional area of the load compensation line 4 electrically connected to the second sub-signal line 112 gradually increases along the direction from the first edge E1 to the second edge E2, including: along the direction from the first edge E1 to the second edge E2, the cross-sectional area of the first sub-compensation line 41 electrically connected to the second sub-signal line 112 gradually increases.

Exemplarily, when the load compensation line 4 only includes the first sub-compensation line 41, lengths of the different load compensation lines 4 are the same, including: different first sub-compensation lines 41 have a same length. Different load compensation lines 4 have the same conductivity, including: different first sub-compensation lines 41 have the same conductivity. Different load compensation lines 4 have the same cross-sectional area, including: different first sub-compensation lines 41 have the same cross-sectional area.

Exemplarily, when the load compensation line 4 includes the first sub-compensation line 41 and the second sub-compensation line 42, the length of the load compensation line 4 electrically connected to the second sub-signal line 112 gradually decreases along the direction from the first edge E1 to the second edge E2, including: along the direction from the first edge E1 to the second edge E2, a sum of lengths of the first sub-compensation line 41 and the second sub-compensation line 42 of the load compensation line 4 electrically connected to the second sub-signal line 112 gradually decreases.

For example, as shown in FIG. 11, in an embodiment of the present disclosure, along the direction from the first edge E1 to the second edge E2, lengths of the first sub-compensation lines 41 of the load compensation lines 4 electrically connected to the second sub-signal lines 112 are the same, and the length of the second sub-compensation line 42 of the load compensation line 4 electrically connected to the second sub-signal line 112 gradually decreases.

Alternatively, in an embodiment of the present disclosure, along the direction from the first edge E1 to the second edge E2, the length of the first sub-compensation line 41 of the load compensation line 4 electrically connected to the second sub-signal line 112 gradually decreases, and lengths of the second sub-compensation lines 42 of the load compensation lines 4 electrically connected to the second sub-signal lines 112 are the same.

Alternatively, in an embodiment of the present disclosure, along the direction from the first edge E1 to the second edge E2, the length of the first sub-compensation line 41 of the load compensation line 4 electrically connected to the second sub-signal line 112 gradually decreases, and the length of the second sub-compensation line 42 of the load compensation line 4 electrically connected to the second sub-signal line 112 gradually decreases.

Exemplarily, when the load compensation line 4 includes the first sub-compensation line 41 and the second sub-compensation line 42, the cross-sectional area of the load compensation line 4 electrically connected to the second sub-signal line 112 gradually increases along the direction from the first edge E1 to the second edge E2, including: along the direction from the first edge E1 to the second edge E2, the cross-sectional area of the first sub-compensation line 41 of the load compensation line 4 electrically connected to the second sub-signal line 112 gradually increases, and/or the cross-sectional area of the second sub-compensation line 42 of the load compensation line 4 electrically connected to the second sub-signal line 112 gradually increases.

For example, in an embodiment of the present disclosure, along the direction from the first edge E1 to the second edge E2, the cross-sectional area of the first sub-compensation line 41 of the load compensation line 4 electrically connected to the second sub-signal line 112 gradually increases, and the cross-sectional areas of the second sub-compensation lines 42 of the load compensation lines 4 electrically connected to the second sub-signal lines 112 are the same.

Alternatively, in an embodiment of the present disclosure, along the direction from the first edge E1 to the second edge E2, cross-sectional areas of the first sub-compensation lines 41 of the load compensation line 4 electrically connected to the second sub-signal lines 112 are the same, and the cross-sectional area of the second sub-compensation line 42 of the load compensation line 4 electrically connected to the second sub-signal line 112 gradually increases.

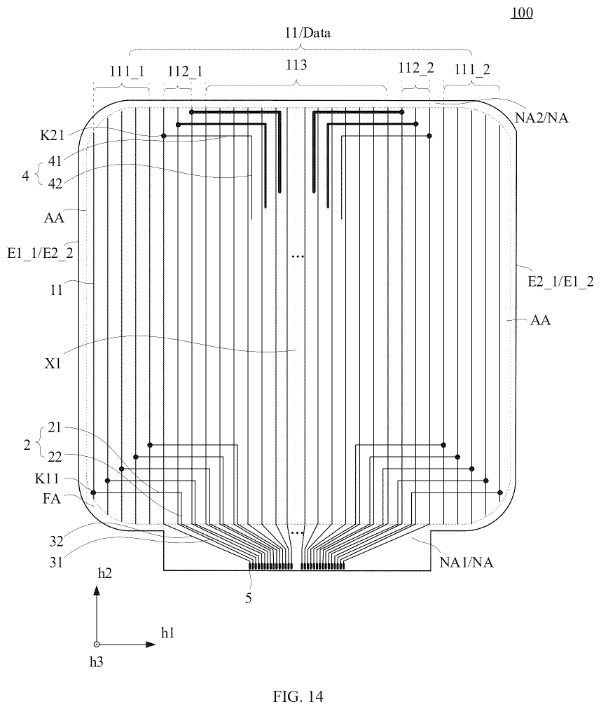

Alternatively, in an embodiment of the present disclosure, along the direction from the first edge E1 to the second edge E2, the cross-sectional area of the first sub-compensation line 41 of the load compensation line 4 electrically connected to the second sub-signal line 112 gradually increases, and the cross-sectional area of the second sub-compensation line 42 of the load compensation line 4 electrically connected to the second sub-signal line 112 gradually increases. As shown in FIG. 14, which is a schematic diagram of another display panel according to an embodiment of the present disclosure, the cross-sectional areas of the first sub-compensation line 41 and the second sub-compensation line 42 in the same load compensation line 4 are the same, and along the direction from the first edge E1 to the second edge E2, the cross-sectional area of the first sub-compensation line 41 of the load compensation line 4 electrically connected to the second sub-signal line 112 gradually increases, and the cross-sectional area of the second sub-compensation line 42 of the load compensation line 4 electrically connected to the second sub-signal line 112 gradually increases.

Exemplarily, when the load compensation line 4 includes the first sub-compensation line 41 and the second sub-compensation line 42, different load compensation lines 4 have the same conductivity, including: conductivities of the first sub-compensation lines 41 of different load compensation lines 4 are the same, and conductivities of the second sub-compensation lines 42 of different load compensation lines 4 are the same. Cross-sectional areas of the different load compensation lines 4 are the same, including: cross-sectional areas of first sub-compensation lines 41 of different load compensation lines 4 are the same, cross-sectional areas of the second sub-compensation lines 42 of different load compensation lines 4 are the same. Different load compensation lines 4 have the same length, including: a sum of the lengths of the first sub-compensation lines 41 and the second sub-compensation lines 42 of each of different load compensation lines 4 is the same. For example, lengths of the first sub-compensation lines 41 of different load compensation lines 4 are the same, and lengths of the second sub-compensation lines 42 of different load compensation lines 4 are the same.

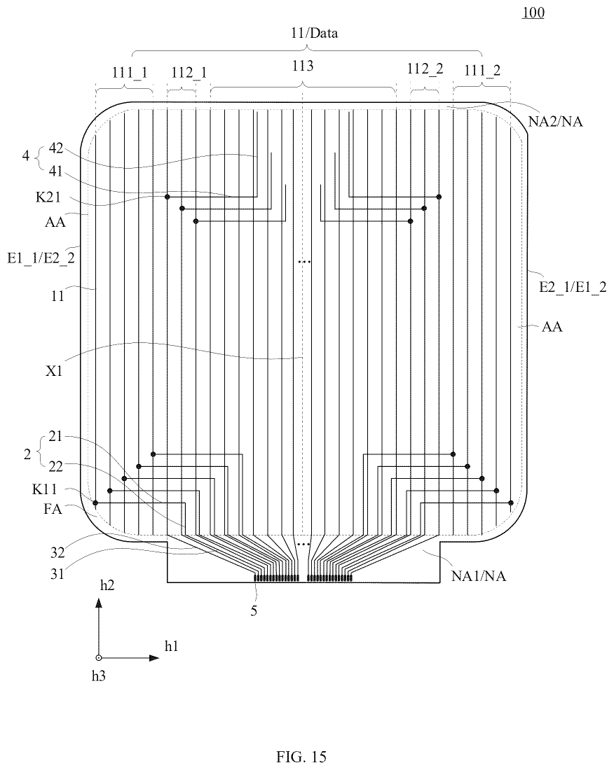

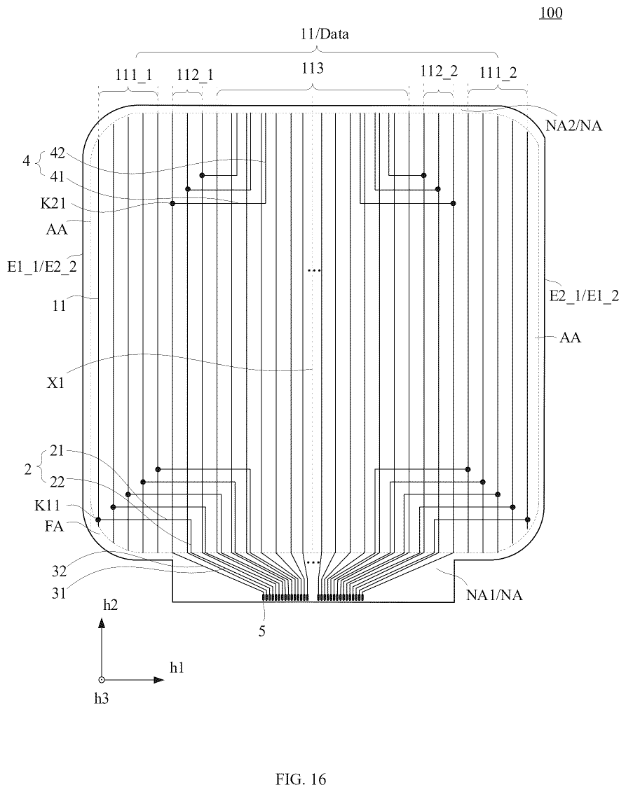

In an embodiment, as shown in FIG. 11 and FIG. 14, the non-display region NA includes a first non-display region NA1 and a second non-display region NA2 arranged along the second direction h2. The display region AA is located between the first non-display region NA1 and the second non-display region NA2. The first non-display region NA1 includes the pin 5, the first fan-out line 31, and the second fan-out line 32. At least part of the second sub-compensation lines 42 is located at a side of the first sub-compensation line 41 close to the first non-display region NA1. Alternatively, as shown in FIG. 15 and FIG. 16, FIG. 15 and FIG. 16 are schematic diagrams of another two display panels according to an embodiment of the present disclosure. In an embodiment of the present disclosure, at least a part of the second sub-compensation lines 42 may be located at a side of the first sub-compensation line 41 close to the second non-display region NA2.

Exemplarily, as shown in FIG. 15, a length of the first sub-compensation line 41 may be the same as a length of the first sub-connection line 21.

Alternatively, as shown in FIG. 16, in an embodiment of the present disclosure, ends of the second sub-compensation lines 42 away from the first sub-compensation lines 41 may be flush along the first direction h1, so as to improve the visual effect.

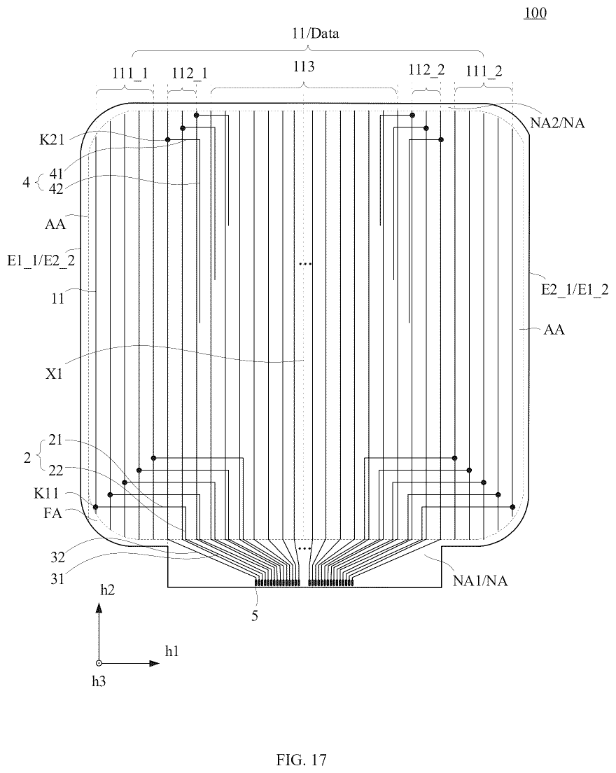

In an embodiment, as shown in FIG. 17, which is a schematic diagram of another display panel according to an embodiment of the present disclosure, the connection line 2 includes a first sub-connection line 21 extending along the first direction h1 and a second sub-connection line 22 extending along the second direction h2, and the first sub-connection line 21 is electrically connected to the second sub-connection line 22. The extension lines of at least some of the second sub-compensation lines 42 to the non-display region overlap with at least some of the second sub-connection lines 22. That is, the extension lines of at least some of the second sub-compensation lines 42 to the non-display region pass through at least some of the second sub-connection lines 22. FIG. 17 illustrates that extension lines of the second sub-compensation lines 42 overlap with different second sub-connection lines 22, respectively. By adopting this arrangement, the forming process is simple and easy to implement, thereby improving the uniformity of line segments.

In an embodiment, as shown in FIG. 7 and FIG. 12, the display region AA further includes second signal lines 12. The second signal lines 12 extend along the first direction h1. The second signal lines 12 intersect with and are insulated from the first signal lines 11. The second signal line 12 is electrically connected to the pixel driving circuit.

As shown in FIG. 7 and FIG. 12, along a direction h3 perpendicular to the plane of the display panel 100, at least part of the second signal lines 12 overlaps with the first sub-connection lines 21, and at least part of the second signal lines 12 overlaps with the first sub-compensation lines 41. In addition, the types of the signals transmitted by the second signal line 12 overlapping with the first sub-connection line 21 and overlapping with the first sub-compensation line 41 are the same. Along the direction h3 perpendicular to the plane of the display panel 100, in an embodiment of the present disclosure, at least part of the second signal lines 12 overlaps with the first sub-connection lines 21, and at least part of the second signal lines 12 overlaps with the first sub-compensation lines 41, thereby making the coupling capacitance of the second signal line 12 received by the first sub-connection line 21 to be consistent with the coupling capacitance of the second signal line 12 received by the first sub-compensation line 41, and thus making the loads thereof to be consistent.

In an embodiment, any one of the first scanning line S1, the second scanning line S2, the light-emitting control signal line E and the reference voltage signal line ref includes the second signal line 12. FIG. 7 and FIG. 12 illustrate a case that the second signal line 12 includes the first reset signal line Ref1, that is, both the first sub-connection line 21 and the first sub-compensation line 41 overlap with the first reset signal line Ref1.

Exemplarily, the first sub-compensation line 41 and the first sub-connection line 21 are arranged in a same layer, and in this way, the first sub-compensation line 41 and the first sub-connection line 21 can be made of a same material in a same patterning process, which is beneficial to simplifying the process flow and reducing the manufacturing cost. FIG. 7 and FIG. 12 illustrate a case that the first sub-compensation line 41 and the first sub-connection line 21 are both located in the fifth metal layer M5.

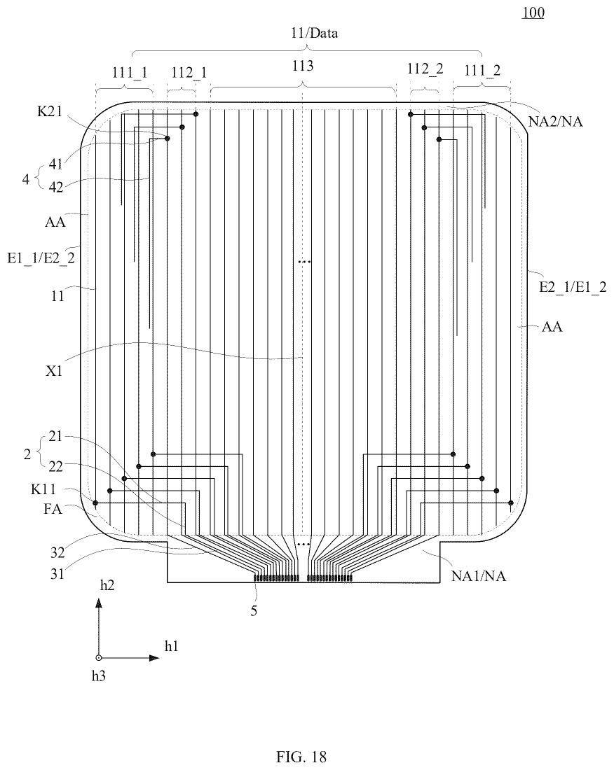

Exemplarily, as shown in FIG. 11, FIG. 14, FIG. 15, FIG. 16 and FIG. 17, in an embodiment of the present disclosure, at least part of the first sub-compensation line 41 may be located at a side of the second sub-signal lines 112 close to the second edge E2. Alternatively, as shown in FIG. 18, which is a schematic diagram of another display panel according to an embodiment of the present disclosure, at least part of the first sub-compensation lines 41 may be located at a side of the second sub-signal lines 112 close to the first edge E1.

Exemplarily, as shown in FIG. 1, FIG. 4, FIG. 5, FIG. 9, FIG. 10, FIG. 11, FIG. 14, FIG. 15, FIG. 16, FIG. 17, and FIG. 18, a distance between the first sub-compensation line 41 and the first sub-connection line 21 is greater than or equal to a distance between two adjacent first sub-connection lines 21. Based on this configuration, the first sub-compensation line 41 and the first sub-connection line 21 can be avoided to be too close, which is beneficial to weakening the interference between the first sub-compensation line 41 and the first sub-connection line 21. In an embodiment, as shown in FIG. 7 and FIG. 12, along the second direction h2, two rows of sub-pixels may be arranged between the first sub-connection line 21 and the first sub-compensation line 41 adjacent thereto.

It should be noted that FIG. 11, FIG. 14, FIG. 15, FIG. 16, FIG. 17, and FIG. 18 only illustrate a case that the load compensation line 4 includes one of the first sub-compensation lines 41 and one of the second sub-compensation lines 42. It may be understood that, in an embodiment of the present disclosure, the load compensation line 4 may also be configured as a zigzag structure including at least two first sub-compensation lines 41 and/or at least two second sub-compensation lines 42, which is not limited in the embodiments of the present disclosure.

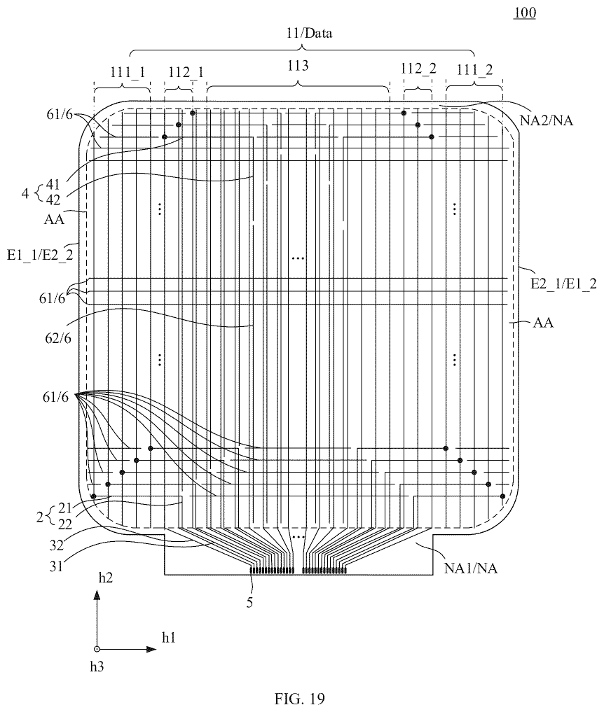

Exemplarily, as shown in FIG. 19, which is a schematic diagram of another display panel according to an embodiment of the present disclosure, the display region AA further includes constant signal lines 6. Extension lines of at least some of the constant signal lines 6 overlap with the load compensation lines 4, and extension lines of at least some of the constant signal lines 6 overlap with the connection lines 2. The constant signal line 6 is configured to transmit a constant signal. In an embodiment, the constant signal includes any one of the first power voltage, the second power voltage, the first reset signal, and the second reset signal. The external ambient light is reflected after illuminating the connection line 2, and the reflected light enters the human eyes, affecting the display effect of the display panel. In an embodiment of the present disclosure, by providing the constant signal line 6 in the region where the load compensation line 4 and the connection line 2 are not provided, the reflection uniformity of the region where the load compensation line 4 and the connection line 2 are provided and the region where the load compensation line 4 and the connection line 2 are not provided to the external ambient light can be improved with the constant signal line 6. Moreover, in an embodiment of the present disclosure, the constant signal line 6 transmits the constant signal required for the operation of the pixel driving circuit, thereby reducing the voltage drop of the corresponding constant signal, and thus improving the brightness uniformity of the display panel 100.

Exemplarily, as shown in FIG. 19, the load compensation line 4 includes a first sub-compensation line 41 extending along the first direction h1 and a second sub-compensation line 42 extending along the second direction h2. The constant signal line 6 includes a first sub-line 61 extending along the first direction h1 and a second sub-line 62 extending along the second direction h2. In an embodiment of the present disclosure, the first sub-line 61 and the first sub-compensation line 41 may be arranged in a same layer, so that the first sub-line 61 and the first sub-compensation line 41 may be formed in a same patterning process with a same material. Furthermore, the second sub-line 62 and the second sub-compensation line 42 may be provided in the same layer, so that the second sub-line 62 and the second sub-compensation line 42 may be formed in a same patterning process with a same material. Exemplarily, the first sub-line 61 is electrically connected to the second sub-line 62.

As shown in FIG. 7 and FIG. 12, the first sub-line 61 and the first sub-compensation line 41 are both located in the fifth conductive layer M5. As shown in FIG. 12, the second sub-line 62 and the second sub-compensation line 42 are both located in the fourth conductive layer M4.

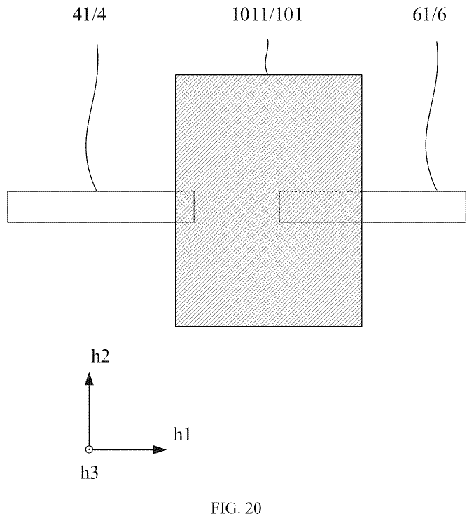

Exemplarily, as shown in FIG. 2, the display region AA includes a light-emitting element 20 electrically connected to the pixel driving circuit 10. The light-emitting element 20 includes a first electrode, a light-emitting layer, and a second electrode that are stacked. In an embodiment, the first electrode includes an anode, and the second electrode includes a cathode. As shown in FIG. 20, which is a schematic diagram of relative positions of a load compensation line, a constant signal line and a first electrode according to an embodiment of the present disclosure, the constant signal line 6 and the load compensation line 4 are spaced apart from each other, and an orthographic projection of the first electrode 1011 onto the plane of the display panel covers a fracture position between the constant signal line 6 and the load compensation line 4. Based on this configuration, the first electrode 1011 may block the fracture position between the constant signal line 6 and the load compensation line 4, thereby avoiding visibility of the fracture position caused by reflection degrees of ambient light at the fracture position between the constant signal line 6 and the load compensation line 4 being different from those at a non-fracture position, and thus avoiding inconsistent visual effects at various positions in the display region AA.

In an embodiment, as shown in FIG. 1, FIG. 4, FIG. 5, FIG. 9, FIG. 10, FIG. 11, FIG. 14, FIG. 15, FIG. 16, FIG. 17, FIG. 18, and FIG. 19, along the direction from the first edge E1 to the second edge E2, the length of the connection line 2 electrically connected to the first sub-signal line 111 gradually increases. In an embodiment of the present disclosure, the lengths of the first sub-connection lines 21 may be the same, and the length of the second sub-connection line 22 may gradually increase, so as to facilitate layout.

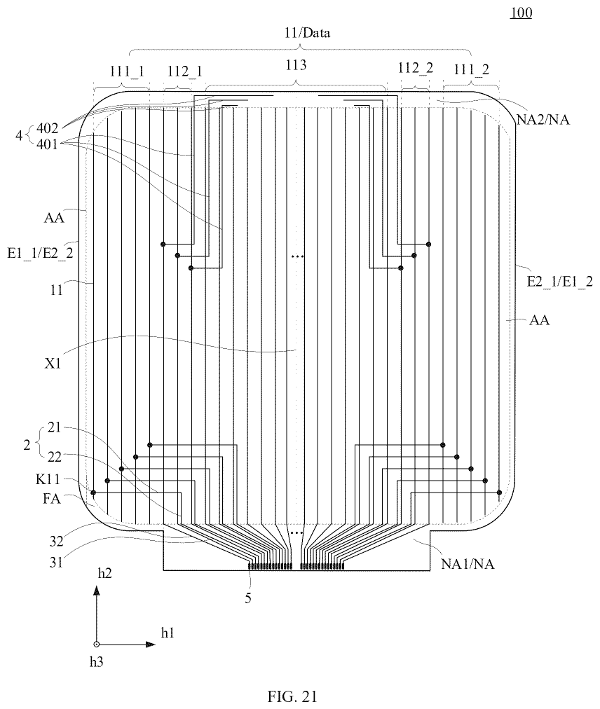

Exemplarily, as shown in FIG. 21, which is a schematic diagram of another display panel according to an embodiment of the present disclosure, at least part of the load compensation lines 4 is located in the non-display region NA to avoid increasing the wiring complexity in the display region AA. FIG. 21 illustrates a case that the load compensation line 4 includes a first portion 401 and a second portion 402 that are electrically connected to each other. The first portion 401 is at least partially located in the display region AA, and the second portion 402 is at least partially located in the non-display region NA.

In an embodiment, the first portion 401 may include a line segment extending along the first direction h1 and/or a line segment extending along the second direction h2. The second portion 402 may include a line segment extending along the first direction h1 and/or a line segment extending along the second direction h2. FIG. 21 illustrates a case that the first portion 401 includes a line segment extending along the first direction h1 and a line segment extending along the second direction h2, and the second portion 402 includes a line segment extending along the first direction h1 and a line segment extending along the second direction h2.

Of course, in an embodiment of the present disclosure, the load compensation lines 4 may also be entirely provided in the non-display region NA, so as to further reduce the wiring complexity in the display region AA, which is not illustrated herein with the accompanying drawings.

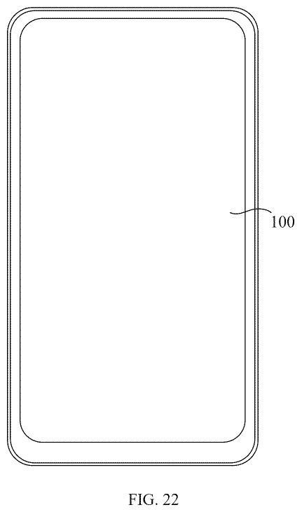

An embodiment of the present disclosure further provides a display device, as shown in FIG. 22, which is a schematic diagram of a display device according to an embodiment of the present disclosure. The display device includes the above-mentioned display panel 100. The specific structure of the display panel 100 has been described in details in the foregoing embodiments, and details are not described herein again. It is understandable that the display device shown in FIG. 22 is merely illustrative, and the display device may be any electronic device having a display function such as a mobile phone, a tablet computer, a notebook computer, an e-book, and a television.

The above description merely illustrates some preferred embodiments of the present disclosure and is not intended to limit the present disclosure, and any modifications, equivalent substitutions, improvements and the like made within the spirit and principle of the present disclosure shall be included within the scope of the present disclosure.

What is claimed is:

1. A display panel, comprising a display region and a non-display region, wherein the display region comprises first signal lines and connection lines, and wherein the first signal lines are arranged along a first direction and extend along a second direction;
the display panel further comprises a first edge and a second edge arranged along the first direction;
the first signal lines comprise at least first sub-signal lines and second sub-signal lines, and the second sub-signal lines are located at a side of the first sub-signal lines away from the first edge;
the non-display region comprises first fan-out lines and second fan-out lines, the connection lines are electrically connected to the first sub-signal lines and the first fan-out lines, and the second fan-out lines are electrically connected to the second sub-signal lines; and
the display panel further comprises load compensation lines electrically connected to the second sub-signal lines; wherein, for resistance values of the load compensation lines that are electrically connected to the second sub-signal lines, the resistance values of at least two of the load compensation lines electrically connected to the second sub-signal lines are different from each other, and the resistance values of the load compensation lines electrically connected to the second sub-signal lines decrease along a direction from the first edge to the second edge.

2. The display panel according to claim 1, wherein
a number of the first sub-signal lines is N1, a number of the second sub-signal lines is N2, a length of one of the connection lines electrically connected to one of the first sub-signal lines adjacent to one of the second sub-signal lines is x, and a length difference between lengths of the load compensation lines electrically connected to two adjacent second sub-signal lines is y,
where N2≤N1, y=x/N2.

3. The display panel according to claim 2, wherein
a length of the connection line electrically connected to the first sub-signal line adjacent to a second sub-signal line is L1, and
a length of a load compensation line electrically connected to the second sub-signal line adjacent to the first sub-signal line is L2,
where L1-L2=x/N2.

4. The display panel according to claim 1, wherein
for lengths of the load compensation lines electrically connected to the second sub-signal lines, the lengths of the load compensation lines electrically connected to at least two of the second sub-signal lines are different from each other, and the lengths of the load compensation lines electrically connected to the second sub-signal lines decrease along the direction from the first edge to the second edge.

5. The display panel according to claim 1, wherein
for cross-sectional areas of the load compensation lines electrically connected to the second sub-signal lines, the cross-sectional areas of the load compensation lines electrically connected to the second sub-signal lines increase along the direction from the first edge to the second edge.

6. The display panel according to claim 1, wherein
at least part of the load compensation lines is located in the display region.

7. The display panel according to claim 6, wherein
one of the connection lines comprises a first sub-connection line extending along the first direction and a second sub-connection line extending along the second direction; and
one of the load compensation lines comprises a first sub-compensation line extending along the first direction.

8. The display panel according to claim 7, wherein
for resistance values of the first sub-compensation lines electrically connected to the second sub-signal lines, the resistance values of the first sub-compensation lines electrically connected to at least two of the second sub-signal lines are different from each other, and the resistance values of the first sub-compensation lines electrically connected to the second sub-signal lines decrease along the direction from the first edge to the second edge.

9. The display panel according to claim 7, wherein
one of the load compensation lines further comprises a second sub-compensation line extending along the second direction, and the second sub-compensation lines and the second sub-connection lines are provided in a same layer.

10. The display panel according to claim 7, wherein
one of the load compensation lines further comprises a second sub-compensation line extending along the second direction, and the second sub-compensation lines and the second sub-signal lines are provided in a same layer.

11. The display panel according to claim 10, wherein
the non-display region comprises a first non-display region and a second non-display region arranged along the second direction, and the display region is located between the first non-display region and the second non-display region; the first non-display region comprises the first fan-out lines and the second fan-out lines;
at least part of the second sub-compensation lines is located at a side of the first sub-compensation lines close to the first non-display region, or
at least part of the second sub-compensation lines is located at a side of the first sub-compensation lines close to the second non-display region.

12. The display panel according to claim 7, wherein
one of the load compensation lines further comprises a second sub-compensation line extending along the second direction, and an extension line of one of at least one of the second sub-compensation lines overlaps one of at least one of the second sub-connection lines.

13. The display panel according to claim 7, wherein
the display region further comprises second signal lines extending along the first direction; and along a direction perpendicular to a plane of the display panel, at least part of the second signal lines overlap with the first sub-connection lines, and at least part of the second signal lines overlap with the first sub-compensation lines.

14. The display panel according to claim 7, wherein
the first sub-compensation lines and the first sub-connection lines are provided in a same layer.

15. The display panel according to claim 7, wherein
the first sub-compensation lines are provided in a layer different from a layer where the second sub-signal lines are provided.

16. The display panel according to claim 7, wherein
a distance between the first sub-compensation line and the first sub-connection line is greater than or equal to a distance between two adjacent first sub-connection lines.

17. The display panel according to claim 6, wherein
the display region further comprises a constant signal line, an extension line of the constant signal line overlaps the load compensation line, and the constant signal line is configured to transmit a constant signal.

18. The display panel according to claim 1, wherein
for lengths of the connection lines electrically connected to the first sub-signal lines, the length of the connection line electrically connected to the first sub-signal line gradually increases along the direction from the first edge to the second edge.

19. The display panel according to claim 1, wherein
at least part of the load compensation line is located in the non-display region.

20. A display device, comprising a display panel, comprising a display region and a non-display region, wherein the display region comprises first signal lines and connection lines, and wherein the first signal lines are arranged along a first direction and extend along a second direction;
the display panel further comprises a first edge and a second edge arranged along the first direction;
the first signal lines comprise at least first sub-signal lines and second sub-signal lines, and the second sub-signal lines are located at a side of the first sub-signal lines away from the first edge;
the non-display region comprises first fan-out lines and second fan-out lines, the connection lines are electrically connected to the first sub-signal lines and the first fan-out lines, and the second fan-out lines are electrically connected to the second sub-signal lines; and
the display panel further comprises load compensation lines electrically connected to the second sub-signal lines; wherein, for resistance values of the load compensation lines that are electrically connected to the second sub-signal lines, the resistance values of at least two of the load compensation lines electrically connected to the second sub-signal lines are different from each other, and the resistance values of the load compensation lines electrically connected to the second sub-signal lines decrease along a direction from the first edge to the second edge.
